(19) United States
(12) Patent Application Publication
(10) Pub. No.: US 2018/0352679 A1
(43) Pub. Date: Dec. 6, 2018

(54) MEMORY DEVICE CARRIER FOR HIGH DENSITY FRONT SERVICEABLE RACK DRIVE CHASSIS

(71) Applicant: Intel Corporation, Santa Clara, CA (US)

(72) Inventors: Blaine R. Monson, Mesa, AZ (US); Pankaj Kumar, Chandler, AZ (US); Anthony K. Wong, Sacramento, CA (US); Uzair A. Qureshi, Chandler, AZ (US)

(73) Assignee: Intel Corporation, Santa Clara, CA (US)

(21) Appl. No.: 15/612,093

(22) Filed: Jun. 2, 2017

(51) Int. Cl. H05K 7/20; H05K 7/14

(52) U.S. Cl. CPC H05K 7/20572; H05K 7/1491; H05K 7/1489; H05K 7/1487; H05K 7/20172; H05K 7/1492; H05K 7/1439

(57) ABSTRACT

A memory device carrier is described that is particular suitable for a high density rack drive chassis in which the drives are front serviceable. In one example, a memory system includes an enclosure configured to mount in a rack, the enclosure having a front configured to receive airflow and a rear configured for cabling, a drawer configured to slide longitudinally in and out of the enclosure, the drawer having a bottom surface and a front face, and a longitudinal connector board mounted to the drawer having a plurality of memory device sockets, the sockets facing outward laterally from the longitudinal board and configured to receive memory devices inserted laterally into a respective socket.

### FIELD

The present description pertains to solid state memory and in particular to high density housings for solid state memory that allow memory devices to be serviced individually.

### BACKGROUND

Mass storage devices for computers have experienced a radical change in cost and size. Not too long ago, the 5.25″ hard disk drive was considered a marvel of speed and compactness with capacities of up to tens of GBs. These were replaced with a 3.5″ form factor, still offered today with capacities in multiple TBs. The 2.5″ Small Form Factor (SFF) hard disk drive was developed as a smaller alternative for notebook computers where low power is more important than speed or capacity. Some notebook computers moved to a similar but smaller 1.8″ ultra small form factor hard disk drive. New computers typically use solid state memory on a card or directly soldered to the motherboard instead of the 1.8″ drive. There are several form factors for the card, such as Mini PCIe (Peripheral Component Interface express), M.2, etc. The deployment of the cards is limited in part by the ubiquity of the hard disk drive form factors and by the cost savings of soldered memory chips directly onto a motherboard or system board.

The old hard disk drive form factors are still in common use. They offer standardization, compatibility with a wide range of different housings, enclosures, cases, and systems and the exterior housing provides protection for the components inside. Standards are already in use for durability and reliability that make it easy to design systems for different applications.

A typical SFF Solid State Drive (SSD) has memory chips and a controller soldered to a system board that is attached to an exterior case. The SFF-compliant case can consist of a simple metal or plastic prismatic box with threaded holes on the top, bottom, and sides, for attaching the case to system mounting points. Reflecting its spinning disc origins, the box is relatively flat with a length and width much greater than its height.

The speed, capacity up to multiple TBs, standard form factor, low power, and ubiquity make the SFF SSD a common choice not only for notebook computers but other applications. They are now commonly used in desktop computing, workstations, servers, memory arrays, and large rack mount systems. The SFF case provides ample room for even more memory capacity as solid state memory increases in density and decreases in cost.

For rack-mount systems and larger memory storage arrays, the overall storage capacity (e.g. total Terabytes for a particular volume, such as 1 unit height of rack space) is compared to storage performance (total bandwidth as measured by Input Output Operations per second (IOPs) per volume, such as 1 unit height of the total rack space). With emerging all flash array storage chassis designs, Terabyte density and IOPs rates are increasing. This is being accomplished by packing more storage devices, such as 2.5″ SSDs into a single chassis. There are now many different ways to pack a large number of memory devices into a 1 U height chassis.

### BRIEF DESCRIPTION OF THE DRAWING FIGURES

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity.

FIG. 1 is an isometric diagram of a 1 U chassis with two slide out memory device trays according to an embodiment.

FIG. 2 is an isometric view of the chassis of FIG. 1 with one drawer drawn partially out frontward away from the rack according to an embodiment.

FIG. 3 is an isometric diagram like the diagram of FIG. 2, showing one of the drives removed according to an embodiment.

FIG. 4 is a front isometric view diagram of the enclosure of FIG. 1 with a top cover removed according to an embodiment.

FIG. 5 is a front isometric view diagram of an alternative enclosure with a top cover removed according to an embodiment.

FIG. 6 is a block diagram of a computing device incorporating memory cases with enhanced cooling according to an embodiment.

### DETAILED DESCRIPTION

For a deployed memory system, memory devices are prone to failure over time. When there are many memory devices in a single chassis with heavy use, then users prefer to have easy access for servicing the drives. This is usually accomplished using some form of redundancy and allowing hot swap/hot plug capability for each drive. This allows the system capacity to be maintained or expanded while the system is in use. As a result, when any one drive fails or requires service, it can be removed and replaced. If it is repaired or restored, then it can be replaced in a different location or even the same location. Most chassis designs provide access to the memory devices through a front of rack chassis access configuration.

Existing rack mount storage arrays provide dense storage in a 1 U or 2 U rack height enclosure, but appear to be limited even in the best cases to 12-15 memory devices, such as 2.5″ SSDs, per unit of rack space. In some cases, the total number of memory devices for each unit of rack space is increased but with the restriction that the hot swap capabilities are restricted to two devices or more at a time. This then requires a change in the management software for the system.

A configuration and new method of arranging memory devices is described herein. It allows for an increased number of devices while retaining the individual hot-plug/hot-swap capabilities that improve data center operations.

As described herein, the total SSD density per unit rack space may be increased by creating drawers (or trays) that position the SSDs in a new orientation. Individual drive access and hot-plug/hot swap are maintained. In some embodiments, per rack unit space is increased to 32 devices per single unit (1 U) space. This could be expanded to higher density numbers depending on the desired storage usage model. As an example for a JBOF (Just a Bunch Of Flash) topology without a compute controller in the system, the number of drives may be increased per unit space. As another example, a third or fourth drawer with rear system access may be added to the system depending on the controller board requirements and power delivery architecture of the end solution point.

The described embodiments are able to provide greater per unit rack density in a data center using industry standard building block form factor devices (U.2). This allows for greater total Terabytes and increased IOPs per unit rack space. Both vectors of density and IOPs are key criteria for data centers and even for workplace and productivity servers and data stores. The described solutions are presented in the context of a standard 19″ rack system but may be adapted to different form factors. Half rack systems may easily be constructed using the described approach. In addition, the described solutions are presented in the context of U.2 standards for 2.5″ SSD, but may be adapted to different form factors for the memory devices.

Embodiments implement drawers of flash array devices arranged on both sides of a single printed circuit board. Utilizing the maximum height available in a standard 1 U chassis, there are two U.2 devices arranged one above the other. Two devices occupy the volume space that is allocated to only one device in other systems and yet embodiments retain single SSD access at any time.

The trays of drives may be attached to a controller board located in the system via a cable assembly that delivers the storage signaling as well as the power for the devices. The cable allows the drawers to slide in and out to expose the memory devices for maintenance while the system continues to operate.

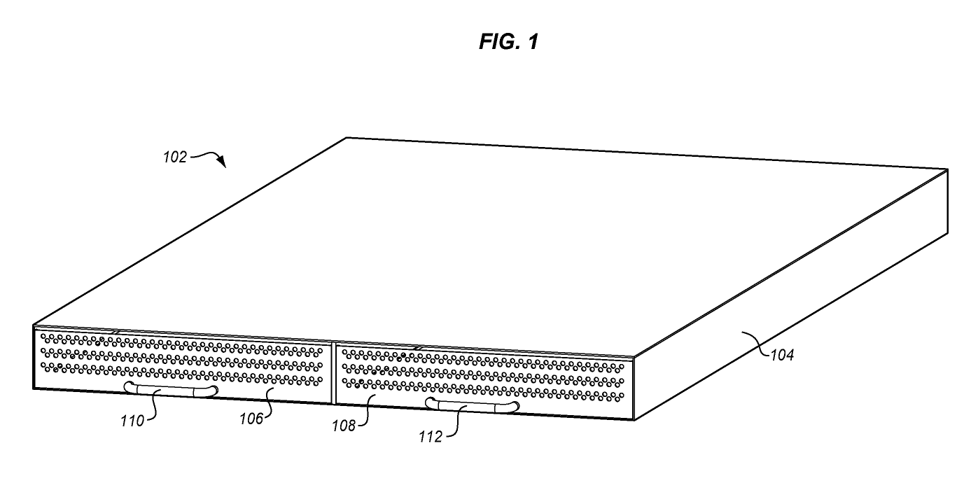

FIG. 1 is an isometric diagram of a 1 U chassis with two slide out memory device trays. The chassis 102 has a main housing 104 to protect the contents and, in some cases to direct air flow across the internal components. The housing carries two drawers or trays 106, 108, each with a corresponding handle 110, 112, to allow access to the memory devices within. The drawers are shown with perforated front plates to allow air flow into the housing. The air is drawn in by internal fans and then exhausted out the back of the rack.

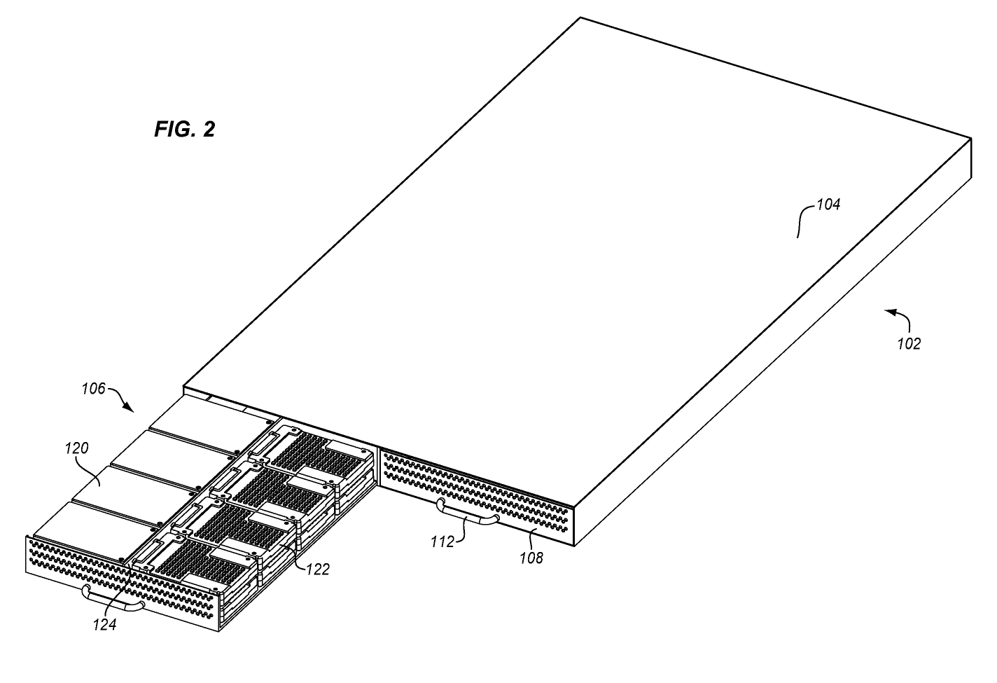

FIG. 2 is an isometric view of the chassis of FIG. 1 with one drawer drawn partially out longitudinally and frontward away from the rack. The drawer is mounted to drawer glides suitable for the weight of the memory devices, such as slides, rollers, wheels, tracked ball bearings, etc. The drawer carries two longitudinal rows of memory devices, such as the 2.5″ SSD memory devices as described above. The row on the left side is two devices high with the drives 120 stacked right side up. The row on the right side is also two devices high with the drives 122 stacked upside down.

There is a connector 124 between the two rows running longitudinally along the center of the drawer. The connector may be in the form of a double-sided printed circuit board (PCB) or any other suitable type of connector. In a standard SATA (Serial Advanced Technology Attachment) HDD (Hard Disk Drive) U.2 form factor, the connector is on the bottom of the drive housing. If the device is upside down, then the connector is at the top. Accordingly, with the drives on one side of the connector inverted as compared to the drives on the other side of the connector, the individual sockets of the connector will be staggered. The left side drive will plug into a socket near the lowest part of the drive housing and the right side drive will plug into a socket at the highest point of the drive housing. This allows all of the drive sockets to be mounted to a single connector PCB. The sockets alternate with left side sockets in one position and right side sockets in the other position.

While the memory devices are shown as all being oriented the same way in each row, any other configuration may be used. As an example, the second position in the row may be upside down relative to the first position in the row. The parallel row on the opposite side of the card may be configured oppositely with the first position upside down and the second position right side up, etc.

While the housing is shown has having two drawers or trays, this may be adapted to suit different sizes of memory devices. A smaller memory device may allow for three drawers and a larger memory device may allow for only one. As an example, for 1.8″ SSDs, there may be two drawers as shown and a third drawer with only one row of memory devices. For 3.5″ SSDs there may be one drawer with two rows and a second narrower drawer with one row. With other memory device configurations, there may be different numbers of drawers. As another example with a wider or narrower rack there may also be more or fewer drawers.

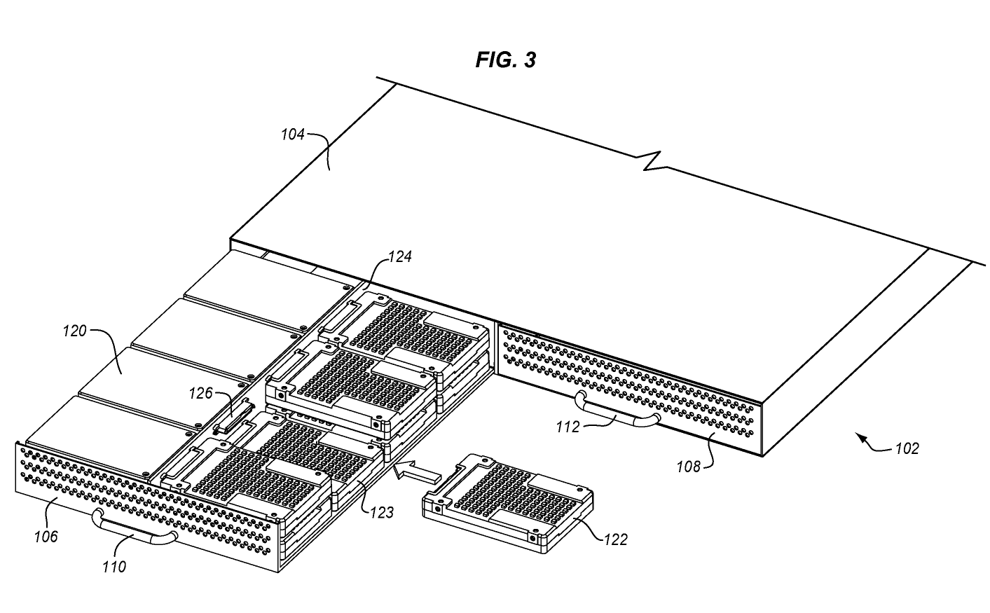

FIG. 3 is an isometric diagram like the diagram of FIG. 2, showing how one of the drives 122 may be removed by sliding it out laterally from the corresponding lateral-facing socket 126 of the connector 124. In this configuration, an upper memory device 122 in the second position of the right side row has been removed and may be reinserted as indicated by the lateral arrow. This shows the second lower memory device 123 below the upper memory device that has been removed so that there is a stack of memory devices that is two devices high one stacked over the other. For a 2 U chassis, the stack may be four devices high. For a thinner memory device such as a 1.8″ SSD or M.2 memory card, the stack may be three or four devices high even in a 1 U chassis.

Each memory device may be supported by side or bottom rails (not shown) or any other suitable structure to hold the case of each memory device in position next to the socket. The rails also support the upper memory device above the lower memory device so that the lower memory device may be removed without affecting the upper memory device. As an alternative, only the upper memory devices rest on side rails and the lower memory devices rest on the bottom of the housing or ribs or pegs along the bottom of the housing.

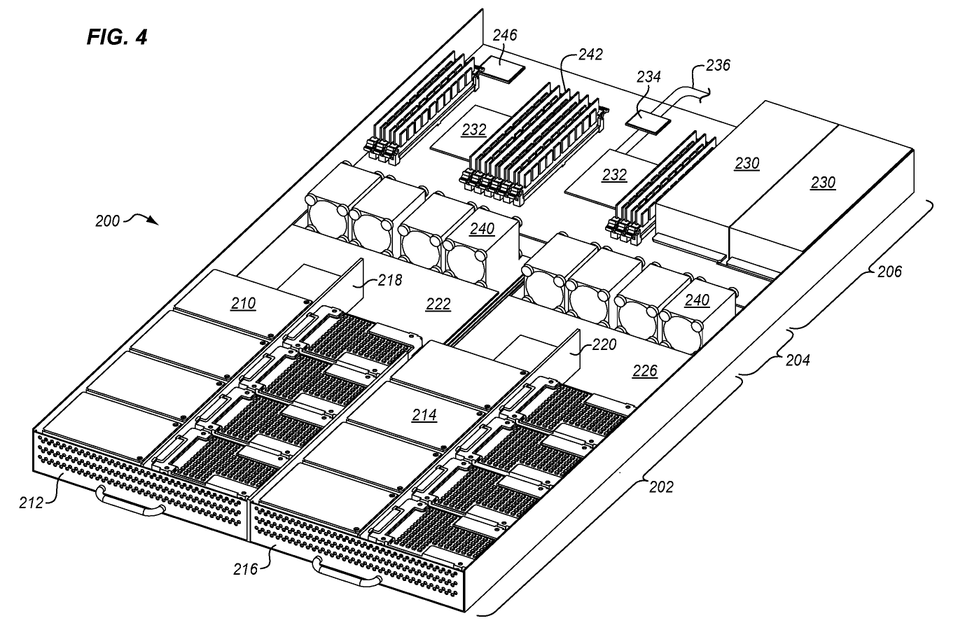

FIG. 4 is an isometric diagram of a chassis enclosure 200 for a 1 U rack height. This configuration may be augmented by an extra layer above or below for additional computing, switching, interface, memory, or power supply resources. The front of the chassis has a memory housing zone 202. In this example, the memory devices 210, 214 are visible in each of the two side-by-side drawers 212, 216 because the top cover of the housing has been removed. This top cover will otherwise act to guide air across and between the memory devices.

The memory devices, 2.5″ SSDs in this example are in two rows in each drawer and stacked two high. They are all connected to a central connector board 218, 220 which runs longitudinally along the drawer. The connector board extends perpendicular or normal to the bottom floor 222, 226 of the drawer 212, 216 and vertically upwards to provide a vertical surface between the two rows and facing the connector of each drive. As mentioned, two boards may be used or a different type of connector may be used. The bottom 222, 226 of each drawer may have a PCB or other connector to electrically connect to the connector board 218, 220.

This bottom PCB connects to a cable or other structure to allow the drawers to move but maintain the connection to the switching, interface, computing and power supply resources at the rear of the enclosure. The cable allows the drawer to move in and out of the enclosure without losing the connection to the fixed components at the rear of the enclosure.

A fan zone 204 is directly behind the drawers to draw air into the drawers and out the rear of the housing. There may be a midplane board (not shown) to hold the fans and provide power or there may be wiring connectors and brackets in the bottom of the housing or the fans may be attached to a PCB of the rear zone. The cable from the memory devices may also be connected to such a midplane board which is then connected to the rear zone. The rear zone is a power supply and management zone 306 that includes power supplies 230 on one or more sides of the enclosure 200.

The fan zone 204 near the center of the enclosure has an array of fans 240 across the width of the chassis. There are eight fans in this example, but there may be more or fewer. The fans pull air from the front of the chassis between the memory devices and then push it out the rear of the enclosure. They may be helped by power supply and compute module fans, if any, and by additional rear fans, if any. The intermediate fan zone is placed between the memory devices and the power supplies and is connected through a midplane PCB or the rear PCB.

In this example there are no front fans shown. Front fans may be used to improve air flow or reduce the load on the middle fans. The front fans may be mounted in each drawer in front of the memory devices or in another location. In this example, the drawers have handles at the front face of each drawer of the enclosure to allow access to the storage devices.

Compute modules 232 may also be placed on the rear board proximate the rear of the enclosure. The compute modules may include external interface components 234 that couple to cabling 236 or another connector. The cabling connects the memory system to external components on another position on the rack or to another rack. The compute modules may be aided by memory modules 242 connected to the compute modules through the PCB and by other supporting chipset or other components 246. The compute modules may be configured to serve and store data and to convert to and from different formats. Alternatively, the compute modules may be more powerful and able to perform simple tasks at low energy or more complex computation and modeling tasks, depending on the particular implementation.

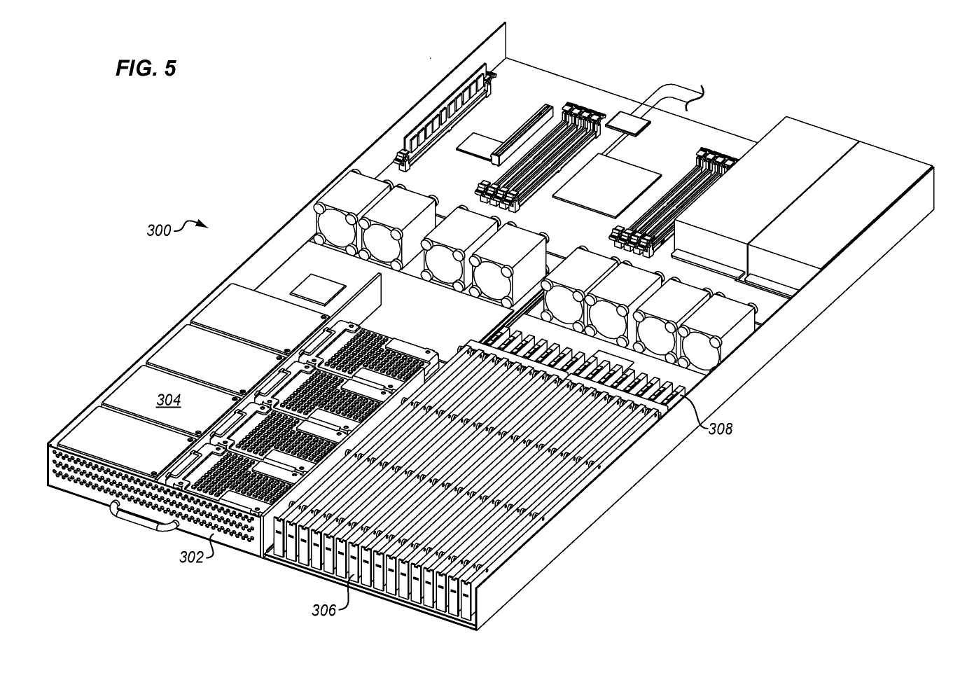

FIG. 5 is an isometric diagram of an alternative chassis enclosure 300 for a 1 U rack height. This configuration supports two different types of memory devices in a single chassis. On one side, there is a drawer 302 filled with 2.5″ SSDs 304 as described above. On the other side an array of elongated memory cards is carried. Each memory card has a bottom or rear connector 308 and may be replaced be pulling from the front or lifting from the top, depending on the particular implementation. The memory cards are shown as being supported directly by the housing of the chassis without a drawer, however, a drawer may be used for easier access similar to the drawer 302 on the right side.

The chassis is otherwise similar to the example of FIG. 4, although there may be modifications to the processors, interfaces, power supplies and any other components to suit particular uses. As shown, the drawer carries two rows of four drives each two drives high for a total of 16 drives in one drawer. The FIG. 4 example carries 32 drives in a 1 U chassis. If the rear zone is made smaller, then there may be room for more drives, e.g. five or six drives in each row. Six drives in four rows two drives high would total 48 drives.

As a further alternative, a narrower drawer that carries only one row of drives may be used. In the example of FIG. 5, this would allow for more of the elongated memory cards to be used. In other cases a narrower drawer may allow more compute, switching, or other components to be provided in the space that would be used for the drives.

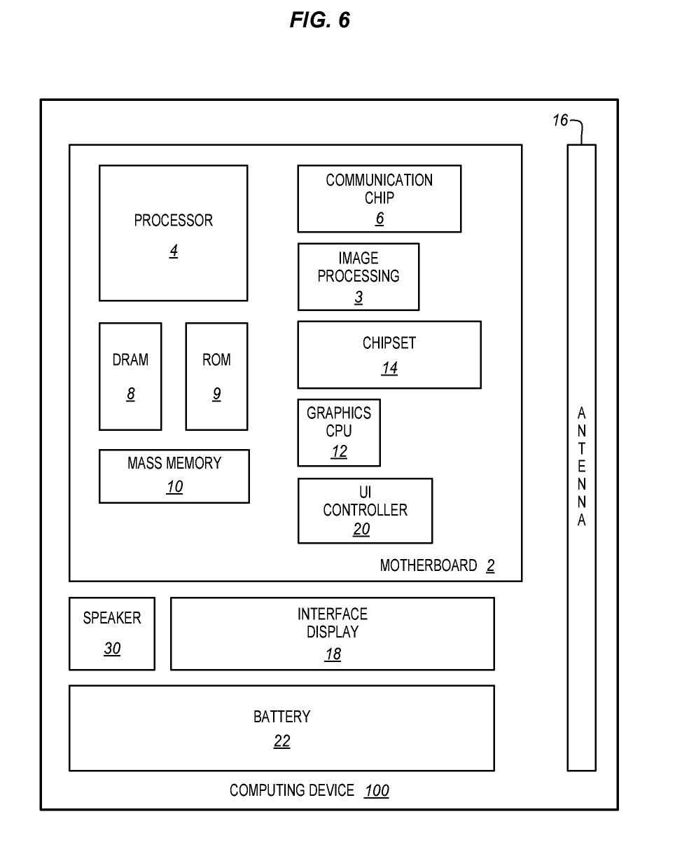

FIG. 6 is a block diagram of a computing device 100 in accordance with one implementation. The computing device 100 houses a system board 2. The board 2 may include a number of components, including but not limited to a processor 4 and at least one communication package 6. The communication package is coupled to one or more antennas 16 or cable connectors. The processor 4 is physically and electrically coupled to the board 2.

Depending on its applications, computing device 100 may include other components that may or may not be physically and electrically coupled to the board 2. These other components include, but are not limited to, volatile memory (e.g., DRAM) 8, non-volatile memory (e.g., ROM) 9, flash memory (not shown), a graphics processor 12, a digital signal processor (not shown), a crypto processor (not shown), a chipset 14, an antenna 16, a display interface 18, a user interface controller 20, a backup battery 22, an audio codec (not shown), a video codec (not shown), a speaker 30, and a mass storage device (such as a hard disk drive) 10, optical disk (CD, DVD, etc.) (not shown), etc. These components may be connected to the system board 2, mounted to the system board, or combined with any of the other components.

The communication package 6 enables wireless and/or wired communications for the transfer of data to and from the computing device 100. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication package 6 may implement any of a number of wireless or wired standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, Ethernet derivatives thereof, as well as any other wireless and wired protocols that are designated as 3G, 4G, 5G, and beyond. The computing device 100 may include a plurality of communication packages 6. For instance, a first communication package 6 may be dedicated to shorter range wireless communications such as Wi-Fi and Bluetooth and a second communication package 6 may be dedicated to longer range wireless communications such as GPS, EDGE, GPRS, CDMA, WiMAX, LTE, Ev-DO, and others.

The computing system may be configured as the rack-mount chassis memory and processing system of e.g. FIGS. 4 and 5. The memory system may have multiple iterations of the computing system within a single enclosure for the overall system in the housing.

In various implementations, the computing device 100 may be an entertainment front end unit or server, a music or video editing station or back end, a cloud services system, a database, or any other type of high performance or high density storage or computing system.

Embodiments may be include one or more memory chips, controllers, CPUs (Central Processing Unit), microchips or integrated circuits interconnected using a motherboard, an application specific integrated circuit (ASIC), and/or a field programmable gate array (FPGA).

References to “one embodiment”, “an embodiment”, “example embodiment”, “various embodiments”, etc., indicate that the embodiment(s) so described may include particular features, structures, or characteristics, but not every embodiment necessarily includes the particular features, structures, or characteristics. Further, some embodiments may have some, all, or none of the features described for other embodiments.

In the following description and claims, the term “coupled” along with its derivatives, may be used. “Coupled” is used to indicate that two or more elements co-operate or interact with each other, but they may or may not have intervening physical or electrical components between them.

As used in the claims, unless otherwise specified, the use of the ordinal adjectives “first”, “second”, “third”, etc., to describe a common element, merely indicate that different instances of like elements are being referred to, and are not intended to imply that the elements so described must be in a given sequence, either temporally, spatially, in ranking, or in any other manner.

The drawings and the forgoing description give examples of embodiments. Those skilled in the art will appreciate that one or more of the described elements may well be combined into a single functional element. Alternatively, certain elements may be split into multiple functional elements. Elements from one embodiment may be added to another embodiment. For example, orders of processes described herein may be changed and are not limited to the manner described herein. Moreover, the actions of any flow diagram need not be implemented in the order shown; nor do all of the acts necessarily need to be performed. Also, those acts that are not dependent on other acts may be performed in parallel with the other acts. The scope of embodiments is by no means limited by these specific examples. Numerous variations, whether explicitly given in the specification or not, such as differences in structure, dimension, and use of material, are possible. The scope of embodiments is at least as broad as given by the following claims.

The following examples pertain to further embodiments. The various features of the different embodiments may be variously combined with some features included and others excluded to suit a variety of different applications. Some embodiments pertain to a memory system that includes an enclosure configured to mount in a rack, the enclosure having a front configured to receive airflow and a rear configured for cabling, a drawer configured to slide longitudinally in and out of the enclosure, the drawer having a bottom surface and a front face, and a longitudinal connector board mounted to the drawer having a plurality of memory device sockets, the sockets facing outward laterally from the longitudinal board and configured to receive memory devices inserted laterally into a respective socket.

Further embodiments include a cable connected to the connector board to couple the connector board to a memory interface in the enclosure.

In further embodiments the connector board further has a second plurality of memory device sockets facing outward laterally from an opposite side of the longitudinal board and configured to receive memory devices inserted laterally from an opposite direction into a respective socket.

In further embodiments the plurality of memory device sockets are configured in two rows on one side of the connector board to receive two rows of memory devices stacked one over the other.

In further embodiments the connector board is configured to receive memory devices on one side of the connector board that are upside-down with respect to the memory devices on the other side of the memory board.

In further embodiments the front face has perforations to allow ventilation through the front face.

Further embodiments include a plurality of fans behind the drawer in the enclosure to draw air to flow through the front face into the enclosure to cool storage devices connected to the connector board.

In further embodiments the connector board is fastened to the drawer bottom surface and extends vertically upward from the bottom surface.

In further embodiments the memory devices have a width and a length greater than their height and wherein the sockets are configured so that the length of the memory device extends laterally when installed in the drawer and the width of the memory device extends longitudinally and wherein the memory devices are placed in stacks of multiple drives.

In further embodiments the chassis enclosure has a 1 U chassis height and wherein the drawer carries two rows of memory devices stacked one row over the other.

In further embodiments the memory devices conform to a U.2 2.5″ form factor.

Further embodiments include a power supply proximate the rear of the enclosure to provide power to the memory devices through the connector card and having a fan to pull air from the front of the enclosure between the memory devices and to push air out the rear of the enclosure.

Further embodiments include a cabling interface at the rear of the enclosure having external connectors.

Further embodiments include a second drawer configured to slide longitudinally in and out of the enclosure independent of the first drawer and a second longitudinal connector board mounted to the second drawer having a plurality of memory device sockets.

Some embodiments pertain to a memory system drawer for a rack mount enclosure that includes a bottom surface and a front face, the front face being perforated to allow air flow through the front face, the drawing being configured to slide so that the front face is pulled away from and toward the enclosure, and a connector board mounted to the drawer bottom surface and extending in the direction of the sliding, the board having a plurality of memory device sockets, the sockets facing outward perpendicular from the length of the board and configured to receive memory devices inserted laterally into a respective socket.

Further embodiments include a second plurality of device sockets on an opposite side of the connector board to receive memory devices from an opposite direction from the first plurality of memory sockets.

In further embodiments the sockets comprise serial connectors for U.2 form factor memory devices, wherein the sockets are in two rows and wherein the sockets on one side of the board are inverted with respect to the sockets on the other side of the board.

Some embodiments pertain to a memory chassis configured to mount in a server rack, the chassis including an enclosure configured to mount in a rack, the enclosure having a front configured to receive airflow and a rear configured for cabling, a plurality of drawers configured to slide longitudinally in and out of the enclosure and parallel to each other in an out of the enclosure, a longitudinal connector board mounted to each drawer having a plurality of memory device sockets, the sockets facing outward laterally from the longitudinal board in two opposing directions from opposite sides of the connector board, the socket configured to receive hot swappable memory devices inserted laterally from either side into a respective socket, a plurality of fans to draw air through the drawers and across the memory devices; and a switch fabric to connect the longitudinal connector boards to external devices.

Further embodiments include a compute module within the enclosure and coupled to the switch fabric.

Further embodiments include a cable to connect the longitudinal connector boards to the switch fabric and permit movement of the respective board.

1. A memory system comprising:
an enclosure configured to mount in a rack, the enclosure having a front configured to receive airflow and a rear configured for cabling;
a drawer configured to slide longitudinally in and out of the enclosure, the drawer having a bottom surface and a front face; and
a connector board mounted longitudinally to the drawer having a plurality of device sockets, the sockets facing outward laterally from the longitudinal board and configured to receive memory devices inserted laterally into a respective device socket, wherein the plurality of device sockets are configured in two rows on one side of the connector board to receive two rows of memory devices stacked one over the other, and wherein the connector board is configured to receive memory devices on one side of the connector board that are upside-down with respect to the memory devices on an opposite of the memory board; and
a connector between the two rows running longitudinally along the center of the drawer, the connector mounting the respective device sockets on both sides of the connector board such that the device sockets on the one side of the connector board alternate positions with the device sockets on the opposite side of the connector board to receive the memory devices on the one side of the connector board that are upside-down with respect to the memory devices on the opposite side of the connector board.

2. The memory system of claim 1, further comprising a cable connected to the connector board to couple the connector board to a memory interface in the enclosure.

3. The memory system of claim 1, wherein the connector board further has a second plurality of device sockets facing outward laterally from an opposite side of the connector board and configured to receive memory devices inserted laterally from an opposite direction into a respective socket.

4. (canceled)

5. (canceled)

6. The memory system of claim 1, wherein the front face has perforations to allow ventilation through the front face.

7. The memory system of claim 6, further comprising a plurality of fans behind the drawer in the enclosure to draw air to flow through the front face into the enclosure to cool storage devices connected to the connector board.

8. The memory system of claim 1, wherein the connector board is fastened to the drawer bottom surface and extends vertically upward from the bottom surface.

9. The memory system of claim 1, wherein the memory devices have a width and a length greater than their height and wherein the sockets are configured so that the length of the memory device extends laterally when installed in the drawer and the width of the memory device extends longitudinally and wherein the memory devices are placed in stacks of multiple drives.

10. The memory system of claim 9, wherein the chassis enclosure has a 1 U chassis height and wherein the drawer carries two rows of memory devices stacked one row over the other.

11. The memory system of claim 10, wherein the memory devices conform to a U.2 2.5″ form factor.

12. The memory system of claim 1, further comprising a power supply proximate the rear of the enclosure to provide power to the memory devices through the connector board and having a fan to pull air from the front of the enclosure between the memory devices and to push air out the rear of the enclosure.

13. The memory system of claim 12, further comprising a cabling interface at the rear of the enclosure having external connectors.

14. The memory system of claim 1, further comprising a second drawer configured to slide longitudinally in and out of the enclosure independent of the first drawer and a second longitudinal connector board mounted to the second drawer having a plurality of device sockets.

15. A memory system drawer for a rack mount enclosure comprising:
a bottom surface and a front face, the front face being perforated to allow air flow through the front face, the drawer being configured to slide so that the front face is pulled away from and toward the enclosure; and
a connector board mounted to the drawer bottom surface and extending in the direction of the sliding, the connector board having a first plurality of device sockets on one side of the connector board facing outward perpendicular from the length of the connector board and configured to receive memory devices inserted laterally into a respective socket, the connector board further comprising a second plurality of device sockets on an opposite side of the connector board to receive memory devices that are upside-down with respect to the memory devices on the other side of the memory board, wherein the device sockets on the one side of the connector board alternate positions with the device sockets on the opposite side of the connector board to receive the memory devices on the one side of the connector board that are upside-down with respect to the memory devices on the opposite side of the connector board.

16. (canceled)

17. The memory system drawer of claim 15, wherein the device sockets comprise serial connectors for U.2 form factor memory devices, wherein the device sockets are in two rows and wherein the device sockets on one side of the board are inverted with respect to the device sockets on the opposite side of the board.

18. A memory chassis configured to mount in a server rack, the chassis comprising:
an enclosure configured to mount in the server rack, the enclosure having a front configured to receive airflow and a rear configured for cabling;
a plurality of drawers configured to slide longitudinally in and out of the enclosure and parallel to each other in an out of the enclosure;
a connector board mounted longitudinally to each drawer having a plurality of device sockets, the device sockets facing outward laterally from the longitudinal board in two opposing directions from opposite sides of the connector board, each of the sockets configured to receive hot swappable memory devices inserted laterally from either side into a respective device socket, wherein the memory devices inserted on one side of the connector board are upside-down with respect to the memory devices on the other side of the memory board, and wherein the device sockets on the one side of the connector board alternate positions with the device sockets on the opposite side of the connector board to receive the memory devices on the one side of the connector board that are upside-down with respect to the memory devices on the opposite side of the connector board;
a plurality of fans to draw air through the drawers and across the memory devices; and
a switch fabric to connect the respective connector boards to external devices.

19. The memory chassis of claim 18, further comprising a compute module within the enclosure and coupled to the switch fabric.

20. The memory chassis of claim 19, further comprising a cable to connect the respective connector boards to the switch fabric and permit movement of the respective connector boards.
